(19) United States
(12) Patent Application Publication
(10) Pub. No.: US 2022/0223384 A1
(43) Pub. Date: Jul. 14, 2022

(54) APPARATUS FOR MANUFACTURING A SEMICONDUCTOR DEVICE

(71) Applicant: Samsung Electronics Co., Ltd., Suwon-si (KR)

(72) Inventors: Naoyuki TAKADA, Yokohama city (JP); Noriaki IMAI, Yokohama city (JP); Takafumi NOGUCHI, Yokohama city (JP); Toshihiro IIZUKA, Yokohama city (JP); Yoshiaki MORIYA, Yokohama city (JP)

(73) Assignee: Samsung Electronics Co., Ltd., Suwon-si (KR)

(21) Appl. No.: 17/570,806

(22) Filed: Jan. 7, 2022

(30) Foreign Application Priority Data
Jan. 14, 2021 (JP) 2021-004114
Sep. 3, 2021 (KR) 10-2021-0117507

(51) Int. Cl. H01J 37/32; H01L 21/683

(52) U.S. Cl. CPC H01J 37/32513; H01J 37/32724; H01J 37/3244; H01J 2237/334; H01J 2237/2007; H01J 2237/002; H01J 37/32082; H01L 21/6833

(57) ABSTRACT

An apparatus for manufacturing a semiconductor device may include a vacuum chamber, an electrostatic chuck (ESC), a cooler, an RF plate, a casing, a base plate and a gas supplier. The ESC may be arranged in the vacuum chamber. The cooler may be configured to cool the ESC. The RF plate may be arranged under the cooler. The casing may be configured to support the cooler. The base plate may be opposite to the RF plate to form an inner space together with the casing. The gas supplier may supply a gas having a low dew point to the inner space. Thus, a generation of the dew condensation at the very low temperature may be prevented so that a damage caused by a short, which may be generated by the dew condensation, may also be prevented.

### CROSS-REFERENCE TO RELATED APPLICATIONS

This application claims priority under 35 USC § 119 to Japanese Patent Application No. 2021-004114, filed on Jan. 14, 2021 and Korean Patent Application No. 10-2021-0117507, filed on Sep. 3, 2021 in the Korean Intellectual Property Office (KIPO), the contents of which are herein incorporated by reference in their entirety.

### BACKGROUND

### 1. Field

Example embodiments relate to an apparatus for manufacturing a semiconductor device.

### 2. Description of the Related Art

A plasma-processing apparatus for manufacturing a semiconductor device may function to etch with a high etching rate or a high etching selectivity by maintaining a low temperature of a wafer. For example, a relation between an etching selectivity of Si/resist and a temperature of the wafer may be disclosed. The etching selectivity may be improved at a temperature of no more than about −50° C.

When a merit of the etching at a low temperature may be caused by a coagulation of plasma, it may be advantageous to provide the wafer with the low temperature. In this case, risks such as a short, a damage, etc., may be generated by a dew condensation at a high voltage used in an electrostatic chuck (ESC). However, there may exist a limit for providing a gas with a low dew point. Because the gas having the low dew point and a dry air may be expensive, it may be required to invest a high cost. Further, the gas having the low dew point capable of responding a cooling at a temperature of no more than about −100° C. Thus, dew condensation may be frequently generated in the apparatus.

Further, technologies and apparatuses for cooling the wafer to the low temperature may be dawning. Thus, responses of the risks may be required on all such occasions.

The ESC may be used in the apparatus for supporting the wafer. The apparatus may include a high frequency power supply. Thus, when a short may be generated between a high voltage terminal and an RD plate by the ESC, functions of the ESC may be disappeared. The short may damage the apparatus.

When any action may not be taken on a low region of a cooled portion, an under structure of the apparatus may also have the low temperature so that the dew condensation may be generated at a portion contacted with an outside air. Further, because the apparatus may include a plurality of cables, an electric leakage may be generated.

In order to remove the risk by the dew condensation, a high temperature may be provided to a base plate contacted with the outside air to reduce or prevent the electric leakage. In order to reduce or prevent the dew condensation causing the short, an inner space of the apparatus may be isolated from an outside. A moisture amount in the apparatus may be minimally decreased.

Conventional art may disclose an apparatus for reducing or preventing a dew condensation. When plasma may be generated to heat an upper electrode of the apparatus, the upper electrode may be cooled.

However, it may not be sufficient to cool the wafer and perform a dry-etching process using the apparatus. Thus, when the dew condensation may be generated, a short may be generated between a high voltage terminal and an RF electrode. Further, when an air current or a moisture amount may not be considered, the dew condensation may also be generated by a local cooling of a gas.

### SUMMARY

Example embodiments provide an apparatus for manufacturing a semiconductor device that may be capable of reducing or preventing a dew condensation.

According to example embodiments, there may be provided an apparatus for manufacturing a semiconductor device. The apparatus may include a vacuum chamber, an electrostatic chuck (ESC), a cooler, an RF plate, a casing, a base plate and a gas supplier. The ESC may be arranged in the vacuum chamber. The cooler may be configured to cool the ESC. The RF plate may be arranged under the cooler. The casing may be configured to support the cooler. The base plate may be opposite to the RF plate to form an inner space together with the casing. The gas supplier may supply a gas having a low dew point to the inner space.

According to example embodiments, the apparatus may reduce or prevent dew condensation and/or damage caused by a short.

In example embodiments, the casing may include at least two parts. O-rings may be interposed between the cooler and the casing, between the parts of the casing and between the casing and the base plate.

According to example embodiments, the inner space filled with the gas and a vacuum region may be sealed.

In example embodiments, the apparatus may further include an RF cable configured to supply a power for generating plasma in the vacuum chamber. O-rings may be interposed between the RF cable and the base plate and between the RF cable and the vacuum chamber.

According to example embodiments, the inner space filled with the gas and an outside air may be sealed.

In example embodiments, the gas supplier may include a gas-supplying member configured to supply the gas having the low dew point into the inner space with a constant pressure.

According to example embodiments, the inner space may be maintained under a positive pressure and the inner space may be filled with the gas having the low dew point. Thus, the outside air including moisture may not infiltrate into the vacuum chamber.

In example embodiments, the O-ring may include a very low temperature-corresponding seal member configured to cover both surfaces of a plasma-resistant seal material. The very low temperature-corresponding seal member may be received in a groove formed at the parts of the casing. The plasma-resistant seal material may be interposed between a gap between the parts of the casing.

According to example embodiments, wear of the O-ring caused by the plasma may be reduced or suppressed. Further, a sealing capacity may be secured at the very low temperature.

In example embodiments, the O-ring may include a flange formed at the plasma-resistant seal material. The flange may have a width wider than a width of a groove in the O-ring.

According to example embodiments, infiltration of the plasma into the groove of the groove may be reduced or prevented to reduce or prevent a damage of the very low temperature-corresponding seal member.

In example embodiments, the apparatus may further include a trap configured to trap moisture in the inner space.

According to example embodiments, the moisture in the inner space may be trapped to reduce or prevent dew condensation.

In example embodiments, the trap may function as to decrease a temperature of a gas in a gap between the RF plate and a block configured to providing a cooling fluid of the cooler to induce the moisture into the trap.

In example embodiments, the apparatus may further include a pipe connected to the block in the inner space. The pipe may be branched from a passage to induce the moisture into the trap.

According to example embodiments, the moisture in the inner space may be trapped to reduce or prevent dew condensation. Further, the moisture adjacent to the ESC or the RF plate may be sufficiently removed.

In example embodiments, the apparatus may further include an acoustic emission (AE) sensor arranged in the inner space of the casing. A friction, a wear, a crack and/or a fracture of the casing may be detected based on amplitude of a vibration and a shape of a vibration waveform detected by the AE sensor.

According to example embodiments, when the casing may be exposed to a high temperature, the casing may be damaged by a temperature difference between the casing and the RF plate. The AE sensor may previously detect the damage of the casing to reduce or prevent a damage of the apparatus.

According to example embodiments, the generation of the dew condensation at the very low temperature may be reduced or prevented. Thus, a damage caused by a short, which may be generated by the dew condensation, may also be reduced or prevented. Further, a damage of the O-ring caused by the plasma may be reduced or prevented to maintain the vacuum. Furthermore, a damage of the casing caused by the temperature difference may also be reduced or prevented.

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a cross-sectional view illustrating an apparatus for manufacturing a semiconductor device in accordance with example embodiments;

FIG. 2 is a contour diagram illustrating a temperature distribution when a gas circulates in an inner space by a pump;

FIG. 3 is a contour diagram illustrating a temperature distribution of a gap between an inner surface of an RF plate and a block of a casing;

FIG. 4 is a contour diagram illustrating a temperature distribution of a gap between an outer surface of an RF plate and a block of a casing;

FIG. 5 is a contour diagram illustrating a temperature distribution when a gas not circulates in an inner space by a pump;

FIG. 6 is a contour diagram illustrating a temperature distribution of the gap between the inner surface of the RF plate and the block of the casing in FIG. 5;

FIG. 7 is a contour diagram illustrating a temperature distribution of the gap between the outer surface of the RF plate and the block of the casing in FIG. 5;

FIG. 8 is a cross-sectional view illustrating an O-ring of a semiconductor fabrication apparatus in accordance with example embodiments;

FIG. 9 is a cross-sectional view illustrating an apparatus for manufacturing a semiconductor device in accordance with example embodiments;

FIG. 10 is a cross-sectional view illustrating an apparatus for manufacturing a semiconductor device in accordance with example embodiments;

FIG. 11 is a graph showing an AE wave form in a friction and wear condition; and

FIG. 12 is a graph showing an AE waveform in a crack and fracture condition.

### DETAILED DESCRIPTION OF EXAMPLE EMBODIMENTS

Hereinafter, example embodiments will be explained in detail with reference to the accompanying drawings.

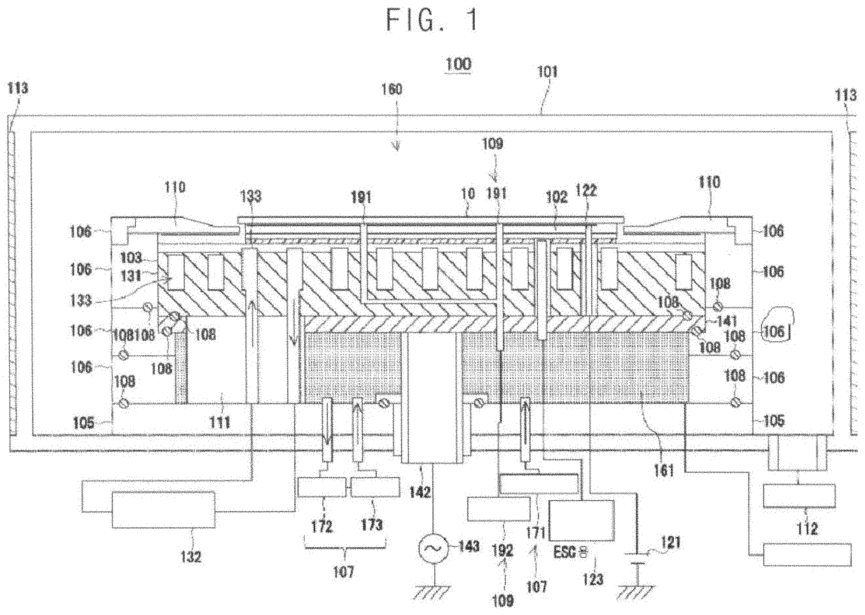

FIG. 1 is a cross-sectional view illustrating an apparatus for manufacturing a semiconductor device in accordance with example embodiments.

Referring to FIG. 1, an apparatus 100 for manufacturing a semiconductor device may include a vacuum chamber 101, an electrostatic chuck (ESC) 102, a cooler 103, a base plate 105, a casing 106, a gas supplier 107, an O-ring 108, a reaction gas supplier 109 and/or a focus ring 110.

Plasma may be generated in a vacuum space 160 over the ESC 102. The apparatus 100 may include an upper electrode. The casing 106 may include at least one part.

The vacuum chamber 101 may be configured to receive the ESC 102, the cooler 103, the base plate 105 and the casing 106. The vacuum chamber 101 may have a vacuum space 160. A heater 113 may heat the vacuum chamber 101. An exhaust apparatus 112 may be configured to provide the vacuum space 160 with vacuum. The exhaust apparatus 112 may include a vacuum pump connected to the vacuum space 160.

The ESC 102 may be configured to fix a substrate 10. The ESC 102 may be arranged in the vacuum chamber 101. A DC power 121 and an HV terminal 122 may be connected to the ESC 102. The DC power may supply a high voltage for fixing the substrate to the ESC 102. The ESC 102 may be positioned on the cooler 103 using an adhesive. The ESC 102 may include an optical fiber thermometer 123.

The cooler 103 may be configured to cool the ESC 102. The cooler 103 may include a cooling plate 131 and a chiller 132. The cooling plate 131 may include a cooling passage 133 through which a cooling fluid may circulate. The chiller 131 may generate the cooling fluid circulating the cooling passage 133.

An RF plate 141 may be opposite to the upper electrode. Thus, the RF plate 141 may function as a lower electrode. The RF plate 141 may be electrically connected with an alternate current power supply 142 through an RF cable 142. The RF power supply 142 may generate a high frequency for generating the plasma. The RF cable 142 may supply the power to the vacuum space 160. The plasma may be generated in the vacuum space 160 over the substrate 10 by supplying the power from through the RF cable 142.

The base plate 105 may be opposite to the RF plate 141. The base plate 105 may form an inner space 161 together with the casing 106. The base plate 105 and a block 111 of the casing 106 may be configured to seal a region under the cooling plate 131.

The casing 106 may be configured to support the RF plate 141 for supporting the cooler 103. The casing 106 may make contact with the cooler 103 and the base plate 105 to form the inner space 161. In order to isolate the RF plate 141 and the base plate 105 from each other, the casing 106 may include ceramic.

The gas supplier 107 may include a gas-supplying member 171. The gas supplier 107 may further include a thermometer 172 and a pump 173. The gas-supplying member 171 may supply a gas having a low dew point to the inner space 161 to provide the inner space 161 with a positive pressure. The thermometer 172 may measure a dew point of the inner space 161. The pump 173 may circulate the gas between the inner space 116 and the thermometer 172. The gas-supplying member 171 may control a pressure of the inner space 161. When the pressure of the inner space 161 may be no more than a predetermined or alternatively, desired value, the gas-supplying member 171 may automatically supply the gas into the inner space 161. Further, when a leakage may be generated, the gas-supplying member 171 may constantly supply the gas to continuously provide the inner space 161 with the positive pressure.

The reaction gas supplier 109 may be configured to supply a reaction gas between the substrate 10 and the ESC 102. The reaction gas supplier 109 may include a nozzle 191 and a controller 192. The nozzle 191 may be electrically connected to the controller 192. The nozzle 191 may inject the reaction gas to the ESC 102. The controller 192 may supply the reaction gas to the nozzle 191.

Hereinafter, simulation results of the cooling by the apparatus 100 may be illustrated in detail.

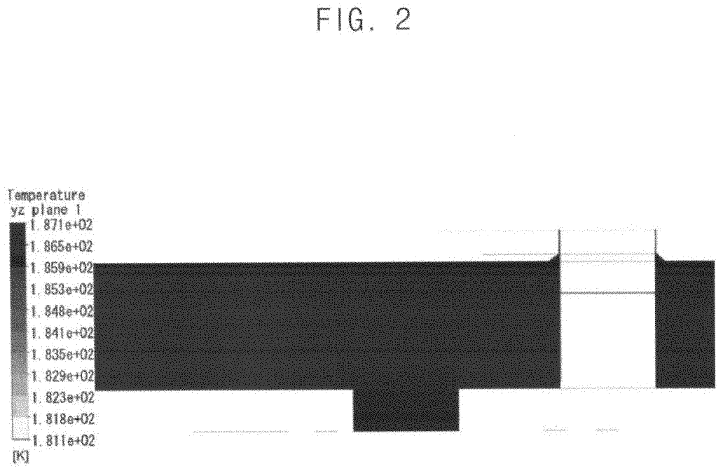

FIGS. 2 to 4 show temperature distributions when the pump 183 in the inner space 161 is operated. FIG. 2 is a contour diagram illustrating a temperature distribution of the gas passing through the block 111 in the inner space 161. In FIG. 2, temperatures are shown by light and shade of a color. Referring to FIG. 2, “−6.522528E-03” may indicate “−6.522528×10⁻³”.

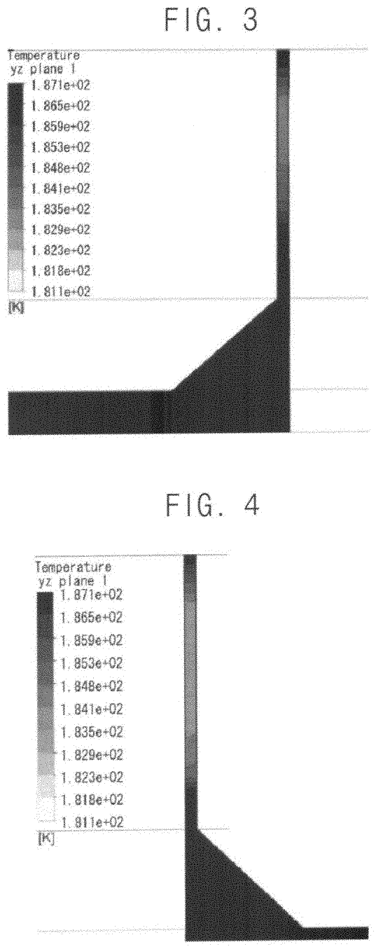

FIG. 3 is a contour diagram illustrating a temperature distribution of a gap between an inner surface of the RF plate and the block of the casing. In FIG. 3, temperatures are shown by light and shade of a color. Further, a left may be oriented toward a central portion and a right may be oriented toward the block 111. FIG. 4 is a contour diagram illustrating a temperature distribution of a gap between an outer surface of the RF plate and the block of the casing. In FIG. 4, temperatures are shown by light and shade of a color. Further, a left may be oriented toward the block 111 and a right may be oriented toward the casing 106.

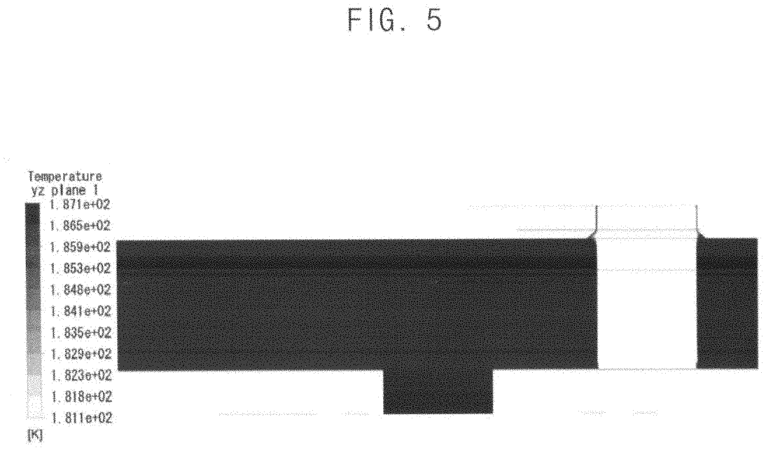

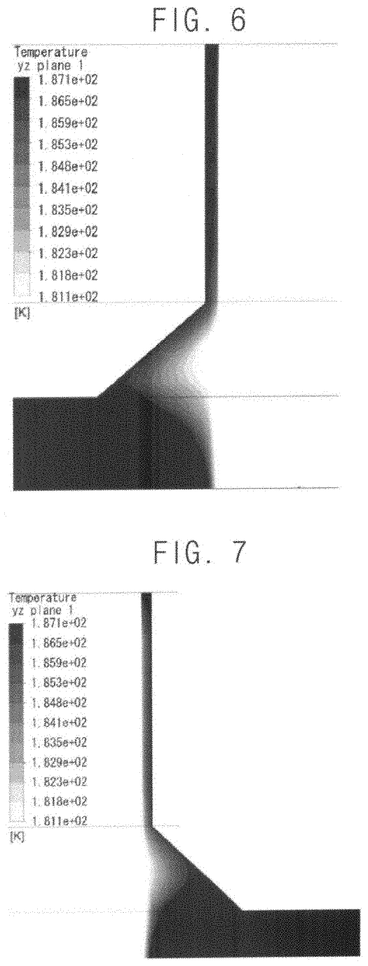

FIGS. 5 to 7 show temperature distributions when the pump 183 in the inner space 161 is not operated. FIG. 5 is a contour diagram illustrating a temperature distribution of the gas passing through the block 111 in the inner space 161. In FIG. 5, temperatures are shown by light and shade of a color. FIG. 6 is a contour diagram illustrating a temperature distribution of the gap between the inner surface of the RF plate and the block of the casing in FIG. 5. In FIG. 6, temperatures are shown by light and shade of a color. Further, a left may be oriented toward a central portion and a right may be oriented toward the block 111. FIG. 7 is a contour diagram illustrating a temperature distribution of the gap between the outer surface of the RF plate and the block of the casing in FIG. 5. In FIG. 7, temperatures are shown by light and shade of a color. Further, a left may be oriented toward the block 111 and a right may be oriented toward the casing 106.

Referring to FIGS. 2 to 4, it can be noted that when the gas may forcibly circulate in the inner space 161 by the pump 183, a temperature of the gas at a high voltage portion in the inner space 161 may not be decreased. Further, it can be noted that the gas flowing through the labyrinth structure between the RF plate 141 and the block 111 may have a minimum temperature to function as a trap for inducing the dew concentration.

In contrast, referring to FIGS. 5 to 7, it can be noted that a temperature of the gas at a high voltage portion in the inner space 161 may not be decreased although a natural convection. Further, it can be noted that the gas flowing through the labyrinth structure between the RF plate 141 and the block 111 may have a minimum temperature to function as a trap for inducing the dew concentration.

The apparatus 100 may be applied to a dry etching apparatus using the plasma. When the apparatus 100 may include the dry etching apparatus, the wafer on the ESC 102 may be maintained at a very low temperature. The cooler 103 may be positioned adjacent to the ESC 102. That is, in order to maintain the very low temperature, the cooling plate 131 may be positioned beneath the ESC 102. The cooling fluid may circulate through the cooling passage 133 to cool the heat.

Further, in order to reduce an expansion of the cooling passage 133 in the inner space 161, the casing 106 may include ceramic. The block 111 may be connected with the cooling plate 131 through the O-ring 108.

Furthermore, a pipe may be connected to the block 111 to previously remove the moisture.

The ESC 102 may be coupled to the HV terminal 122. The RF plate 141 may be arranged under the cooling plate 131. The cooling plate 131 may be coupled to the alternate current power supply 142 through the RF cable 142. In order to isolate the inner space 161 from the outside air, the base plate 105 may be positioned under the RF plate 141. Outer connections may be sealed.

When the block 111 may make contact with the RF plate 141 or the cooling plate 131, the RF plate 141 may be cooled to accelerate the dew concentration of the RF plate 141. Thus, the O-ring 108 may be interposed between the block 111 and the RF plate 141 and between the block 111 and the cooling plate 131. Because a temperature of the O-ring 108 may be decreased to a temperature of the block 111, the O-ring 108 may include a material usable at the temperature of the block 111.

In order to reduce or prevent the dew concentration between the base plate 105 and the outside, a heater may be installed under the base plate 105 to maintain the high temperature of the base plate 105. Alternatively, a heating element 113 in the vacuum chamber 101 may heat the base plate 105. Thus, the dew concentration of the base plate 105 may be reduced or prevented by maintaining the high temperature of the base plate 105. As a result, an electric leakage caused by a water drop on a cable under the base plate 105 may also be reduced or prevented.

When the dew concentration may be generated in the inner space 161, a pump 173 may circulate a fluid to reduce or prevent temperatures of portions in the inner space 161 from being decreased under a dew point. Further, in order to reduce or prevent a direct contact between the fluid from the pump 173 and the RF plate 141, a diffusion plate may be arranged at an inlet to assist the flow in the inner space 161. The pump 173 may provide the fluid to improve a measurement accuracy of the thermometer 172.

Further, before a low temperature process, the inner space 161 may be purged by the gas having the low dew point from the gas-supplying member 171. The inner space 161 may be maintained at the positive pressure. That is, because the temperature of the inner space 161 may be decreased under the low temperature process to drop the pressure of the inner space 161, the pressure of the inner space 161 may be controlled to provide the inner space 161 with the positive pressure.

According to example embodiments, the inner space 161 may be filled with the gas having the low dew point and the inner space 161 may have the positive pressure. Thus, the outside air may not infiltrate into the apparatus. The trap may remove the tiny moisture in the inner space 161 to reduce or prevent the dew concentration.

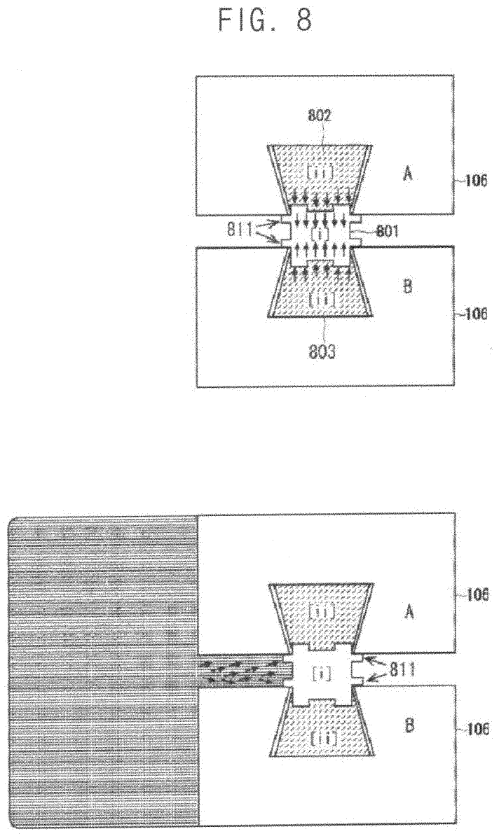

FIG. 8 is a cross-sectional view illustrating an O-ring of a semiconductor fabrication apparatus in accordance with example embodiments.

Referring to FIG. 8, the O-ring 108 may include an O-ring 801, an O-ring 802 and/or an O-ring 803. The O-ring 801 may include a plasma-resistant material. Further, the O-ring 801 may include a wear-resistant material so that particles including a metal may not be generated from the O-ring 803.

The O-ring 802 and the O-ring 803 may include a material having elasticity for maintaining the vacuum at a temperature of about −110° C.

The O-ring 801 may be positioned between the O-ring 802 and the O-ring 803.

In order to attach the O-rings 801 to the casing 106, a dovetail groove may be formed at the two parts of the casing 106.

Generally, a low temperature-resistant material may have a low radical-resistant property and high plasma consumption. When the O-rings 801, 802 and 803 may be exposed to the very low temperature, although the O-ring 801 may be inwardly contracted, the O-ring 802 may be expanded by the contraction of the O-ring 801, because the O-ring 802 may have the very low temperature-resistant property, to have the sealing capacity.

Further, the O-ring 801 may include a flange 811. The flange 811 may have a width wider than a width of the O-ring 801. When the O-ring 801 may be exposed to the plasma, the flange 811 may block the infiltration of the plasma into the O-ring 802 to reduce or prevent the O-ring 802 from being exposed to the plasma.

According to example embodiments, the plasma-resistant seal material may be arranged at a position from the gap to which the plasma may reach. The very low temperature-corresponding seal member may cover the plasma-resistant material at a position from the gap to which the plasma may not reach. Thus, the wear of the O-ring caused by the plasma may be suppressed to secure the sealing capacity at the very low temperature.

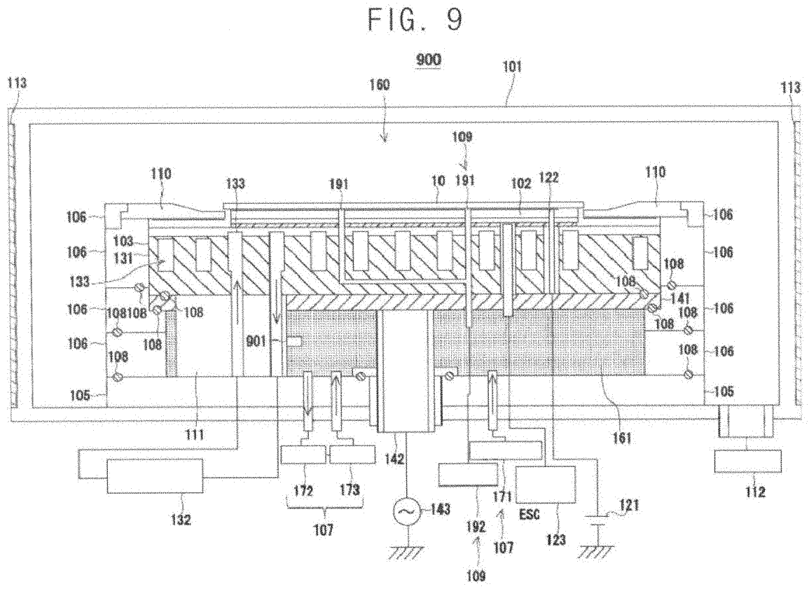

FIG. 9 is a cross-sectional view illustrating an apparatus for manufacturing a semiconductor device in accordance with example embodiments. In FIG. 9, the same reference numerals may refer to the same elements and any further illustrations with respect to the same elements may be omitted herein for brevity.

Referring to FIG. 9, an apparatus 900 for manufacturing a semiconductor device may include a vacuum chamber 101, an ESC 102, a cooler 103, a base plate 105, a casing 106, a gas supplier 107, an O-ring 108, a reaction gas supplier 109, a focus ring 110 and/or a trap 901.

Plasma may be generated in a vacuum space 160 over the ESC 102. The apparatus 900 may include an upper electrode. The casing 106 may include at least one part.

The trap 901 may be configured to trap tiny moisture in the inner space 161. The trap 901 may be connected to the cooling passage 133 from the cooler 103 through a pipe. The trap 901 may function as to trap the moisture on a surface exposed to the inner space 161 at a minimum temperature.

According to example embodiments, the trap may trap the moisture in the inner space to reduce the moisture in the inner space. The temperature of the gas in the gap between the RF plate 141 and the block 111 may be decreased to trap the moisture, which may be caused by the dew concentration, in the trap 901. Further, the pipe branched from the cooling passage 133 may be connected to the block 111 to trap the moisture in the trap 901.

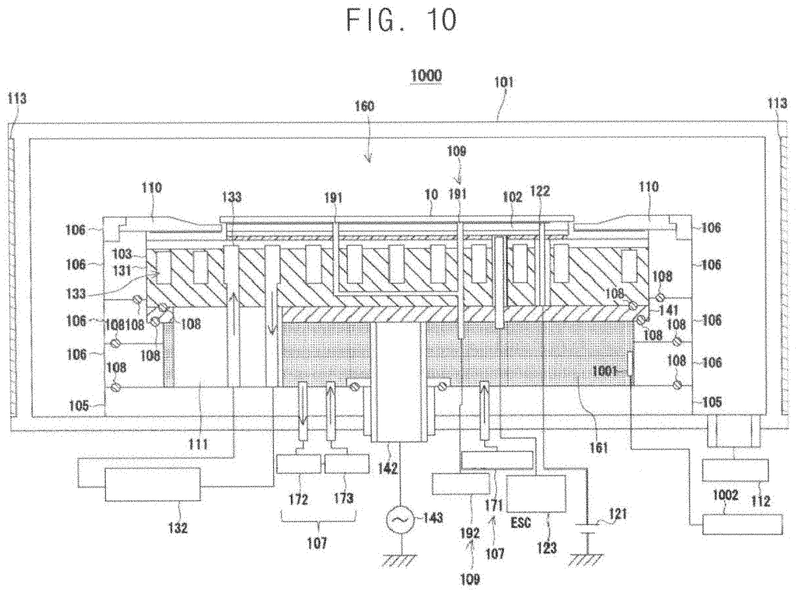

FIG. 10 is a cross-sectional view illustrating an apparatus for manufacturing a semiconductor device in accordance with example embodiments. In FIG. 10, the same reference numerals may refer to the same elements and any further illustrations with respect to the same elements may be omitted herein for brevity.

Referring to FIG. 10, an apparatus 1000 for manufacturing a semiconductor device may include a vacuum chamber 101, an ESC 102, a cooler 103, a base plate 105, a casing 106, a gas supplier 107, an O-ring 108, a reaction gas supplier 109, a focus ring 110, an AE sensor 1001 and/or an AE sensor circuit 1002.

Plasma may be generated in a vacuum space 160 over the ESC 102. The apparatus 1000 may include an upper electrode. The casing 106 may include at least one part.

The AE sensor 1001 may convert amplitude of a vibration of the casing into an electrical signal. The AE sensor 1001 may then output the electrical signal to the AE sensor circuit 1002.

The AE sensor circuit 1002 may detect an electrical signal generated by a friction and a wear between the two pars of the casing 106 from the amplitude detected by the AE sensor 1001. Further, the AE sensor circuit 1002 may detect an electrical signal for predicting a fracture of the casing 106.

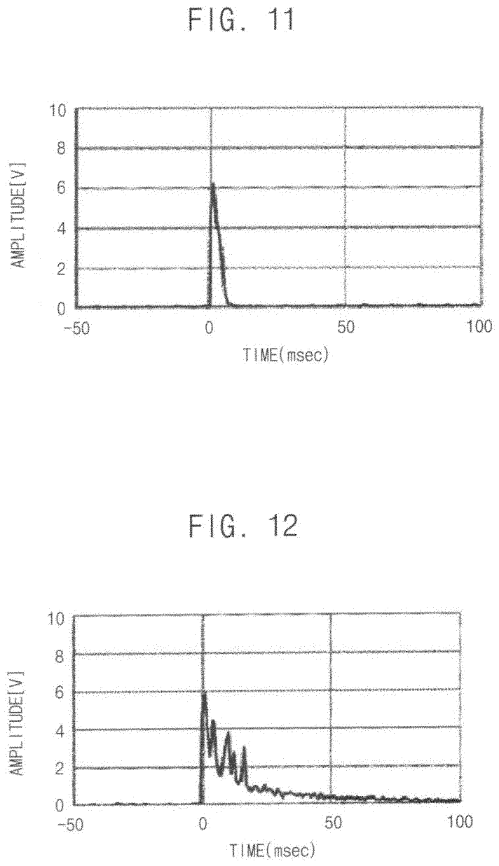

FIG. 11 is a graph showing an AE waveform in a friction and wear condition, and FIG. 12 is a graph showing an AE waveform in a crack and fracture condition. In FIGS. 11 and 12, a horizontal axis may represent a time and a vertical axis may represent amplitude.

When the AE sensor circuit 1002 may detect an AE waveform in FIG. 11 or FIG. 12, the AE sensor circuit 1002 may output the detected results. A friction, a wear, a crack and/or a fracture of the casing 106 may be detected based on amplitude of a vibration and a shape of a vibration waveform detected by the AE sensor 1001.

According to example embodiments, when the casing may be exposed to a high temperature, the casing may be damaged by a temperature difference between the casing and the RF plate. The AE sensor may previously detect the damage of the casing to reduce or prevent a damage of the apparatus. Further, a controller may analyze the shape of the AE waveform. The controller may notice the phenomenon in the vacuum chamber 101 such as an alarm.

The present inventive concepts may not be restricted within the above-mentioned example embodiments. For example, the above-mentioned example embodiments may be variously combined with each other.

Further, the temperature of the example embodiments may be a temperature for generating the dew concentration with respect to a room air. For example, because the gas having the low dew point may not be easily secured, the functions of the example embodiments may be exhibited at a temperature of no more than about −60° C. However, because the seal member may have a restricted cold resistance, the functions of the example embodiments may not be exhibited at a temperature of −110° C.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of example embodiments and is not to be construed as limiting thereof. Although example embodiments have been described, those skilled in the art will readily appreciate that many modifications are possible in the example embodiments without materially departing from the novel teachings and/or advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An apparatus for manufacturing a semiconductor device, the apparatus comprising:
a vacuum chamber;
an electrostatic chuck (ESC) in the vacuum chamber;
a cooler configured to cool the ESC;
a casing configured to support the cooler through an RF plate;
a base plate being opposite to the RF plate configured to support the casing; and
a gas supplier configured to supply a gas having a low dew point to an inner space defined by the RF plate, the casing and the base plate.

2. The apparatus of claim 1, wherein the casing comprises at least two parts, and an O-ring is between the cooler and the casing, between the at least two parts and between the casing and the base plate.

3. The apparatus of claim 1, further comprising:
an RF cable configured to supply a power to the vacuum chamber to generate plasma; and
an O-ring between the RF cable and the base plate and between the RF cable and portions configured to make contact with the vacuum and the base plate.

4. The apparatus of claim 1, wherein the gas supplier comprises a gas-supplying member configured to supply the gas having the low dew point into the inner space at a constant pressure.

5. The apparatus of claim 2, wherein the O-ring comprises a plasma-resistant seal material and a very low temperature-corresponding seal member configured to cover both surfaces of the plasma-resistant seal material, the very low temperature-corresponding seal member is in a groove formed by the at least two parts, and the plasma-resistant seal material is in a gap between the at least two parts.

6. The apparatus of claim 5, wherein the O-ring comprises a flange at the plasma-resistant seal material, and the flange has a width wider than a width of the O-ring.

7. The apparatus of claim 1, further comprising a trap configured to trap moisture in the inner space.

8. The apparatus of claim 7, wherein the trap is configured to decrease a temperature of a gas in a gap between the RF plate and a block configured to provide a cooling fluid of the cooler to induce the moisture into the trap.

9. The apparatus of claim 7, wherein a pipe branched from a cooling passage is connected to a block in the inner space to induce the moisture into the trap.

10. The apparatus of claim 1, further comprising an acoustic emission (AE) sensor in the inner space of the casing, and a friction, a wear, a crack and/or a fracture of the casing are detected based on amplitude of a vibration and a shape of a vibration wave form detected by the AE sensor.
